(19) United States
(12) Patent Application Publication
(10) Pub. No.: US 2025/0169164 A1
(43) Pub. Date: May 22, 2025

(54) HIGH-FREQUENCY INTEGRATED CIRCUIT AND ELECTRONIC DEVICE

(71) Applicant: SONY SEMICONDUCTOR SOLUTIONS CORPORATION, KANAGAWA (JP)

(72) Inventors: KATSUHIKO TAKEUCHI, KANAGAWA (JP); ATSUSHI KURANOUCHI, KANAGAWA (JP)

(21) Appl. No.: 18/711,872

(22) PCT Filed: Oct. 11, 2022
(86) PCT No.: PCT/JP2022/037890

§ 371 Date: Jan. 24, 2025

(30) Foreign Application Priority Data
Nov. 26, 2021 (JP) 2021-192215

(51) Int. Cl. H10D 84/80; H10D 30/47; H10D 62/83; H10D 64/27

(52) U.S. Cl. CPC H10D 84/817; H10D 30/47; H10D 62/83; H10D 64/411

(57) ABSTRACT

A high-frequency integrated circuit (1) of an embodiment of the present disclosure includes: a high-frequency circuit (10); a terminal (20) electrically coupled to the high-frequency circuit; a first transistor (M1) provided between the terminal and a reference potential line; and a second transistor (M2) provided between the terminal and the reference potential line. The first transistor includes a gate (G) and a drain (D) that are electrically coupled to the terminal, and a source (S) electrically coupled to the reference potential line. The second transistor includes a source (S) electrically coupled to the terminal, and a gate (G) and a drain (D) that are electrically coupled to the reference potential line.

### TECHNICAL FIELD

The present disclosure relates to a high-frequency integrated circuit and an electronic device.

### BACKGROUND ART

There is proposed a high-frequency integrated circuit provided with, as a protection device, an enhancement-type field-effect transistor including a gate coupled to GND (the ground) through a resistor.

### CITATION LIST

### Patent Literature

PTL 1: Japanese Unexamined Patent Application Publication No. 2006-114618

### SUMMARY OF INVENTION

It is expected of a high-frequency integrated circuit to prevent ESD damage.

It is desirable to provide a high-frequency integrated circuit that makes it possible to suppress ESD damage.

A high-frequency integrated circuit of an embodiment of the present disclosure includes: a high-frequency circuit; a terminal electrically coupled to the high-frequency circuit; a first transistor provided between the terminal and a reference potential line; and a second transistor provided between the terminal and the reference potential line. The first transistor includes a gate and a drain that are electrically coupled to the terminal, and a source electrically coupled to the reference potential line. The second transistor includes a source electrically coupled to the terminal, and a gate and a drain that are electrically coupled to the reference potential line.

An electronic device of an embodiment of the present disclosure includes: a high-frequency circuit: a terminal electrically coupled to the high-frequency circuit; a first transistor provided between the terminal and a reference potential line; and a second transistor provided between the terminal and the reference potential line. The first transistor includes a gate and a drain that are electrically coupled to the terminal, and a source electrically coupled to the reference potential line. The second transistor includes a source electrically coupled to the terminal, and a gate and a drain that are electrically coupled to the reference potential line.

### BRIEF DESCRIPTION OF DRAWINGS

FIG. 1 is a diagram illustrating a configuration example of a high-frequency integrated circuit according to an embodiment of the present disclosure.

FIG. 2 is a diagram illustrating a configuration example of a transistor of the high-frequency integrated circuit according to the embodiment of the present disclosure.

FIG. 3 is a diagram illustrating an example of electric characteristics of the transistor of the high-frequency integrated circuit according to the embodiment of the present disclosure.

FIG. 4 is a diagram illustrating an example of electric characteristics of the parallel-coupled transistors of the high-frequency integrated circuit according to the embodiment of the present disclosure.

FIG. 5 is a diagram illustrating a configuration example of a high-frequency integrated circuit according to Modification Example 1 of the present disclosure.

FIG. 6 is a diagram illustrating an example of electric characteristics of a transistor of the high-frequency integrated circuit according to Modification Example 1 of the present disclosure.

FIG. 7 is a diagram illustrating an example of electric characteristics of transistors of the high-frequency integrated circuit according to Modification Example 1 of the present disclosure.

FIG. 8 is a diagram illustrating an example of electric characteristics of the parallel-coupled transistors of the high-frequency integrated circuit according to Modification Example 1 of the present disclosure.

FIG. 9 is a diagram illustrating another configuration example of the high-frequency integrated circuit according to Modification Example 1 of the present disclosure.

FIG. 10 is a diagram illustrating an example of an ESD evaluation result of the high-frequency integrated circuit according to Modification Example 1 of the present disclosure.

FIG. 11 is a diagram illustrating a configuration example of a high-frequency integrated circuit according to Modification Example 2 of the present disclosure.

FIG. 12 is a diagram illustrating a configuration example of a high-frequency integrated circuit according to Modification Example 3 of the present disclosure.

FIG. 13 is a diagram illustrating another configuration example of the high-frequency integrated circuit according to Modification Example 3 of the present disclosure.

FIG. 14 is a diagram illustrating a configuration example of a wireless communication apparatus of the present disclosure.

### MODES FOR CARRYING OUT THE INVENTION

With reference to the drawings, an embodiment of the present disclosure will be described in detail below. It is to be noted that the description will be given in the following order.
1. Embodiment
2. Modification Examples
3. Application Example

### 1. Embodiment

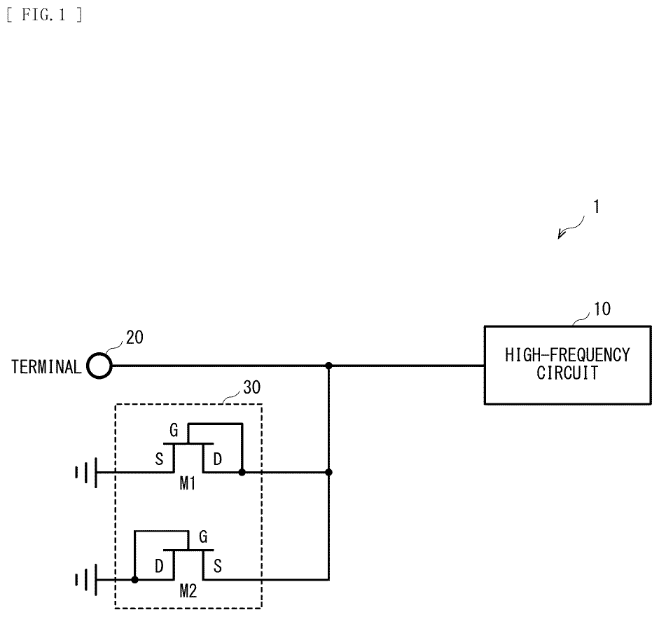

FIG. 1 is a diagram illustrating a configuration example of a high-frequency integrated circuit according to an embodiment of the present disclosure. As illustrated in FIG. 1, a high-frequency integrated circuit 1 includes a high-frequency circuit 10, a terminal 20, and a protection circuit 30. The high-frequency integrated circuit 1 is a circuit that processes a high-frequency signal. The high-frequency integrated circuit 1 is, for example, a communication device, and is able to be used in an electronic device that uses such a frequency band as a millimeter-wave band or a microwave band. The high-frequency circuit 10 is, for example, a power amplifier for a RF signal, a filter, etc. It is to be noted that a high-frequency may be a high-frequency in a band of several MHz to several hundred of GHz or higher. For example, a high-frequency signal in the millimeter-wave band or some other band may be input and output to the high-frequency integrated circuit 1. The frequency of the high-frequency signal may be, for example, 100 MHz or higher, or may be 1 GHz or higher. Furthermore, the frequency of the high-frequency signal may be, for example, 300 GHz or lower, or may be 100 GHz or lower.

The high-frequency integrated circuit 1 is formed with, for example, GaN (gallium nitride). GaN has a wide bandgap and a high breakdown field strength. Furthermore, GaN has a high melting point: thus, it is possible to make use of GaN as a material for a high-frequency device.

The terminal 20 of the high-frequency integrated circuit 1 is electrically coupled to the high-frequency circuit 10. The terminal 20 is, for example, a signal terminal used for transmission of a signal to and from the outside. As an example, the terminal 20 is an input and output terminal that a signal is input and output. It is to be noted that the terminal 20 may be an input terminal to which a signal is input from the outside of the high-frequency integrated circuit 1, or may be an output terminal that outputs a signal to the outside of the high-frequency integrated circuit 1.

The protection circuit 30 is a circuit that protects an internal circuit (in FIG. 1, the high-frequency circuit 10) of the high-frequency integrated circuit 1 to be protected. The protection circuit 30 is electrically coupled to the terminal 20, and protects the high-frequency circuit 10 from an abnormal current and voltage generated through the terminal 20. As will be described later, the protection circuit 30 includes two transistors coupled by different coupling methods, and suppresses the application of a surge caused by static electricity, etc. that a human body or an apparatus is charged with to the high-frequency circuit 10. The protection circuit 30 may be said to be an electrostatic discharge (ESD) protection device that protects the high-frequency circuit 10. It is to be noted that FIG. 1 illustrates only one terminal 20 and one protection circuit 30; however, the high-frequency integrated circuit 1 may be provided with multiple terminals and multiple protection circuits.

The protection circuit 30 includes a transistor M1 and a transistor M2. The transistor M1 is provided between the terminal 20 and a reference potential line. In the example illustrated in FIG. 1, the reference potential line is a grounding wire (a ground wire). The transistor M2 is also provided between the terminal 20 and the grounding wire that is the reference potential line. The transistors M1 and M2 are both a MIS transistor (MISFET) including terminals of a gate, a source, and a drain. The transistors M1 and M2 are both a metal-insulator-semiconductor (MIS) field-effect transistor (FET), and have a MIS gate structure.

The transistors M1 and M2 are both an NMOS transistor. Furthermore, in the present embodiment, the transistors M1 and M2 are both an enhancement-type transistor. Respective threshold voltages of the transistors M1 and M2 are higher than 0 V. The transistors M1 and M2 may be said to be a normally-off transistor. The transistors M1 and M2 and devices used in the high-frequency circuit 10, for example, an FET of an RF amplifier for transmission, a passive device, etc. are formed on the same substrate.

As illustrated in FIG. 1, the drain of the transistor M1 is electrically coupled to the terminal 20. Furthermore, the drain of the transistor M1 is electrically coupled to the high-frequency circuit 10 and the source of the transistor M2. The gate of the transistor M1 is electrically coupled to the drain of the transistor M1. That is, the transistor M1 includes the gate and the drain coupled to each other; in other words, the transistor M1 is a diode-coupled transistor. The source of the transistor M1 is coupled to the grounding wire. The source of the transistor M1 is applied with 0 V that is a grounding potential.

The source of the transistor M2 is electrically coupled to the terminal 20. Furthermore, the source of the transistor M2 is electrically coupled to the high-frequency circuit 10 and the drain of the transistor M1. The drain of the transistor M2 is coupled to the grounding wire. The drain of the transistor M2 is applied with 0 V that is a grounding potential. Furthermore, the gate of the transistor M2 is electrically coupled to the drain of the transistor M2. That is, the transistor M2 includes the gate and the drain coupled to each other: in other words, the transistor M2 is a diode-coupled transistor.

The transistors M1 and M2 are coupled to each other in parallel. As described above, the gate and the drain of the transistor M1 are coupled to the terminal 20 side, and the source of the transistor M1 is coupled to the grounding wire side. The gate and the drain of the transistor M2 are coupled to the grounding wire side, and the source of the transistor M2 is coupled to the terminal 20 side. The transistor M1 goes into an on-state (a conductive state) or an off-state (a non-conductive state) depending on a potential difference between the gate coupled to the terminal 20 and the source coupled to the grounding wire. Furthermore, the transistor M2 goes into the on-state or the off-state depending on a potential difference between the gate coupled to the grounding wire and the source coupled to the terminal 20.

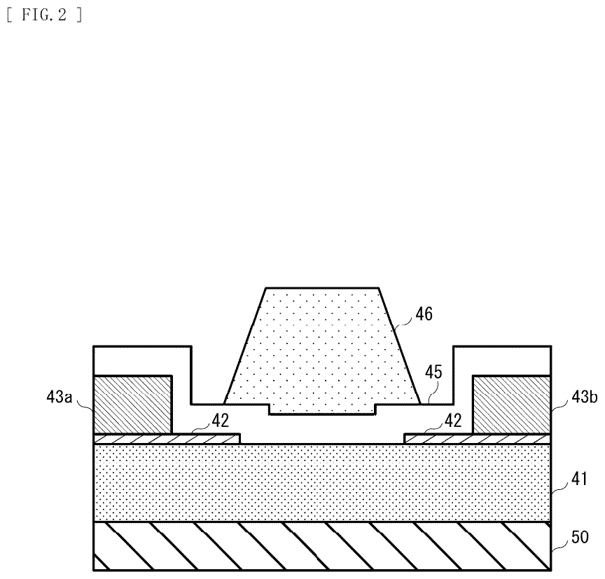

FIG. 2 is a diagram illustrating a configuration example of a transistor of the high-frequency integrated circuit according to the embodiment of the present disclosure. The transistors M1 and M2 used in the protection circuit 30 both have, for example, a structure illustrated in FIG. 2. The high-frequency integrated circuit 1 includes a substrate 50. On the substrate 50, the high-frequency circuit 10, the protection circuit 30, etc. of the high-frequency integrated circuit 1 are formed. For example, the substrate 50 includes Si (silicon), III-V compound semiconductor material, etc. In the present embodiment, the substrate 50 includes a Si substrate. It is to be noted that the substrate 50 may include some other substrate such as a SiC substrate or a sapphire substrate.

For example, as illustrated in FIG. 2, the transistor of the high-frequency integrated circuit 1 includes a channel layer 41, a barrier layer 42, an electrode 43a, an electrode 43b, a gate insulating film 45, and a gate electrode 46. The channel layer 41 includes GaN (gallium nitride). For example, the channel layer 41 is a GaN epitaxial growth layer. The barrier layer 42 includes, for example, Al_{1-x-y}GaₓIn_{y}N (0≤x<1, 0≤y<1), and is provided on the channel layer 41. Polarization occurs between the channel layer 41 and the barrier layer 42, and two-dimensional electron gas is generated at a heterojunction interface. The transistor illustrated in FIG. 2 is a high electron mobility transistor (HEMT). It is to be noted that a buffer layer including AlN, AlGaN, GaN, or the like may be provided between the substrate 50 and the channel layer 41.

The electrodes 43a and 43b both include, for example, titanium (Ti), aluminum (Al), nickel (Ni), gold (Au), or the like. The electrodes 43a and 43b are an ohmic electrode. In FIG. 2, the electrode 43a is provided on the barrier layer 42 on the left side, and the electrode 43b is provided on the barrier layer 42 on the right side. The electrode 43a is an electrode of, of a source and a drain of the transistor, either one, for example, a source electrode. The electrode 43b is an electrode of, of the source and the drain of the transistor, the other one, for example, a drain electrode. It is to be noted that a regrowth layer for lowering the resistance may be provided below each of the electrodes 43a and 43b. As an example, the barrier layer 42 and the channel layer 41 below the electrode 43a are partially removed by etching, and, as a regrowth layer, a semiconductor layer (for example, n-type In₁₋ₓGaₓN (0≤x<1)) may be formed on the respective removed portions by a selective regrowth method. This makes it possible to reduce the resistance between the electrode 43a and the channel layer 41. Likewise, by providing a regrowth layer below the electrode 43b, it becomes possible to reduce the resistance between the electrode 43b and the channel layer 41.

The gate insulating film 45 is provided to cover respective surfaces of the channel layer 41 and the barrier layer 42. The gate insulating film 45 is formed with, for example, a single-layer film including one of silicon oxide (SiO₂), aluminum oxide (Al₂O₃), hafnium oxide (HfO), and the like, or a multi-layered film including two or more of these. The gate electrode 46 includes nickel (Ni), gold (Au), or the like. The film thickness, the shape, etc. of the gate insulating film 45 are set to allow the transistors M1 and M2 to have a desired pinch-off voltage and a desired gate withstand voltage. The transistors M1 and M2 are both provided on the substrate 50, and are electrically coupled to the high-frequency circuit 10 provided on the same substrate 50.

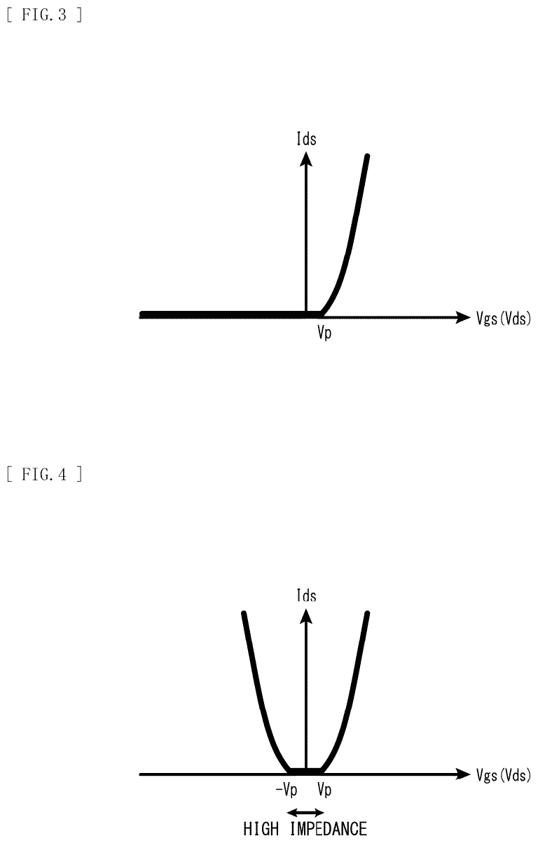

FIG. 3 is a diagram illustrating an example of electric characteristics of the transistor of the high-frequency integrated circuit 1 according to the embodiment of the present disclosure. In FIG. 3, the horizontal axis indicates a voltage Vgs applied between a gate and the source of the transistor. The vertical axis indicates a current Ids flowing between the drain and the source of the transistor. The transistor M1 of the protection circuit 30 is in a state where the gate and the drain are shorted as described above, and has current-voltage characteristics represented by the voltage Vgs (=Vds) and the current Ids illustrated in FIG. 3. The transistor M2 is also in a state where the gate and the drain are shorted as described above, and has the current-voltage characteristics illustrated in FIG. 3.

As illustrated in FIG. 3, when the voltage Vgs is less than a pinch-off voltage Vp, the transistor goes into the off-state (the non-conductive state) and a high-impedance state. It is to be noted that the pinch-off voltage Vp corresponds to a threshold voltage. When the voltage Vgs is greater than or equal to the pinch-off voltage Vp, the transistor goes into the on-state (the conductive state). In this case, the current Ids that is a drain current increases, and the transistor goes into a low-impedance state. It is to be noted that a high impedance is, for example, a case where the current Ids is less than or equal to 1 μA. When a direct-current voltage applied to the terminal 20 is −5 V, a current flowing through the transistor M1 or M2 may be less than or equal to 1 μA.

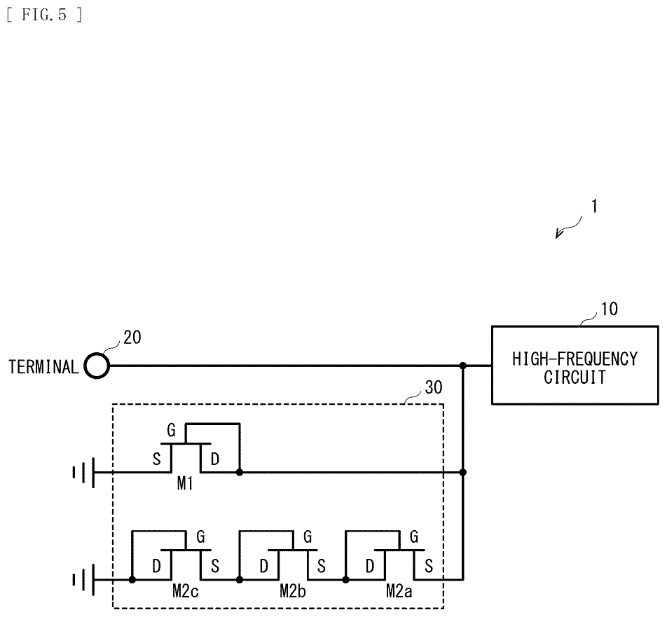

FIG. 4 is a diagram illustrating an example of electric characteristics of the parallel-coupled transistors M1 and M2 of the high-frequency integrated circuit 1 according to the embodiment of the present disclosure. When the value of the voltage Vgs, i.e., the voltage of the terminal 20 based on the grounding wire is within a range of −Vp to +Vp, the transistors M1 and M2 both go into the off-state and the high-impedance state. When the voltage of the terminal 20 is greater than or equal to +Vp, the transistor M1 goes into the on-state and the low-impedance state. Furthermore, when the voltage of the terminal 20 is less than or equal to −Vp, the transistor M2 goes into the on-state and the low-impedance state.

When a positive surge voltage, i.e., a steeply rising surge voltage is applied to the terminal 20, a drain voltage and a gate voltage of the transistor M1 of the protection circuit 30 rise. When the gate voltage of the transistor M1 exceeds the pinch-off voltage (+Vp), as described above, the transistor M1 goes into the on-state, which makes it possible to output a current generated from the surge voltage. Electrical continuity is established between the source and the drain of the transistor M1, and a charge emission pathway is formed between the terminal 20 and the grounding wire. Thus, the current flows between the terminal 20 and the grounding wire through the transistor M1.

In this way, when a positive surge voltage is applied, the protection circuit 30 allows a current to flow between the terminal 20 and the grounding wire through the transistor M1 going into the low-impedance state. The transistor M1 may be said to be a transistor for a positive surge. An excess charge generated in the terminal 20 is discharged through the transistor M1, which makes it possible to suppress the rise in voltage of the terminal 20. The protection circuit 30 makes it possible to suppress the flow of a surge current that is an instantaneous large current into the high-frequency circuit 10.

When a negative surge voltage, i.e., a steeply dropping surge voltage is applied to the terminal 20, a source voltage of the transistor M2 of the protection circuit 30 drops. When the source voltage of the transistor M2 becomes less than or equal to the pinch-off voltage (−Vp), the transistor M2 goes into the on-state, which makes it possible to output a current generated from the surge voltage. Electrical continuity is established between the source and the drain of the transistor M2, and a charge emission pathway is formed between the terminal 20 and the grounding wire. Thus, the current flows between the terminal 20 and the grounding wire through the transistor M2.

In this way, when a negative surge voltage is applied, the protection circuit 30 allows a current to flow between the terminal 20 and the grounding wire through the transistor M2 going into the low-impedance state. An excess charge generated in the terminal 20 is discharged through the transistor M2, which makes it possible to suppress the drop in voltage of the terminal 20.

As described above, in the high-frequency integrated circuit 1 according to the present embodiment, with respect to positive ESD, the transistor M1 for a positive surge goes into the low-impedance state and passes a current to protect the high-frequency circuit 10. Furthermore, with respect to negative ESD, the transistor M2 for a negative surge goes into the low-impedance state and passes a current to protect the high-frequency circuit 10. It is possible to protect the high-frequency circuit 10 from a noise signal of high voltage amplitude such as ESD.

The high-frequency integrated circuit 1 according to the present embodiment is provided with both the transistor M1 for a positive surge and the transistor M2 for a negative surge, and therefore is able to protect the high-frequency circuit 10 from a surge whether it is a positive surge or a negative surge. Furthermore, the surge is discharged by the on-operation of the transistor M1 or the on-operation of the transistor M2; therefore, it is also possible to prevent the breakdown of the transistors M1 and M2 themselves that are a protection device. In the present embodiment, it is possible to suppress the damage to the inside of the high-frequency circuit 10, and is possible to suppress the occurrence of characteristic degradation and ESD damage of the high-frequency circuit 10.

Furthermore, in the present embodiment, when the terminal 20 is an input terminal or an input and output terminal, although it differs according to the function of the high-frequency circuit 10, as an example, the magnitude of DC voltage applied to the terminal 20 is about −5 to +1 V. Furthermore, the respective pinch-off voltages Vp of the transistors M1 and M2 are, for example, 6 V. Thus, in the entire voltage range of a high-frequency signal to be input (a signal to be transmitted), the transistors M1 and M2 go into the high-impedance state, which makes it possible to appropriately transmit the high-frequency signal to the high-frequency circuit 10. Moreover, it is possible to prevent the flow of an unwanted current into the transistors M1 and M2 and avoid an increase in power consumption. It is to be noted that also when the terminal 20 is an output terminal, in the entire voltage range of a high-frequency signal to be output (a signal to be transmitted), it is possible to put the transistors M1 and M2 into the high-impedance state, and possible to appropriately transmit the high-frequency signal to the outside through the terminal 20.

Moreover, in the present embodiment, as compared with a case where an external diode is provided as a protection device, it is possible to reduce the parasitic capacitance added to the terminal 20 and the high-frequency circuit 10. The capacitance of the transistors M1 and M2 is sufficiently low; thus, it is possible to prevent adversely affecting, for example, a RF signal input to the terminal. Furthermore, the transistors used in the protection circuit 30 may have a similar structure to a transistor used in the high-frequency circuit 10. In the present embodiment, it is possible to suppress the worsening of characteristics of the high-frequency circuit 10.

It is to be noted that if an external diode is provided, there is a possibility that a high-frequency circuit may be broken by ESD generated in a manufacturing process before the external diode is mounted. Meanwhile, the high-frequency integrated circuit 1 according to the present embodiment is provided with the protection circuit 30, which makes it possible to suppress ESD damage in a manufacturing process.

### [Action and Effects]

The high-frequency integrated circuit 1 according to the present embodiment includes the high-frequency circuit 10, the terminal 20 electrically coupled to the high-frequency circuit 10, a first transistor (the transistor M1) provided between the terminal 20 and the reference potential line, and a second transistor (the transistor M2) provided between the terminal 20 and the reference potential line. The first transistor includes the gate and the drain that are electrically coupled to the terminal 20, and the source electrically coupled to the reference potential line. The second transistor includes the source electrically coupled to the terminal 20, and the gate and the drain that are electrically coupled to the reference potential line.

The high-frequency integrated circuit 1 according to the present embodiment includes the transistor M1 for a positive surge and the transistor M2 for a negative surge. Thus, it is possible to protect the high-frequency circuit 10 from a surge whether it is a positive surge or a negative surge, and is possible to suppress the occurrence of ESD damage. Furthermore, it is also possible to suppress ESD damage in the transistors M1 and M2 used as a protection device.

Subsequently, modification examples of the present disclosure will be described. In the following, a similar component to the above-described embodiment is assigned the same reference numeral, and its description is omitted accordingly.

### 2-1. Modification Example 1

For example, the film thickness of the gate insulating film 45 may be adjusted to allow the transistors of the protection circuit 30 to have a desired pinch-off voltage. For example, the film thickness of the gate insulating film 45 may be increased to raise the pinch-off voltage. Furthermore, on the basis of the voltage range of a signal to be input or output to the terminal 20, the transistor for a positive surge and the transistor for a negative surge may be formed with a gate insulating film having a different film thickness from each other. For example, the gate insulating film of the transistor M2 may have a larger film thickness than that of the gate insulating film of the transistor M1. It is to be noted that the gate insulating film of the transistor M1 may have a larger film thickness than that of the gate insulating film of the transistor M2.

Moreover, the protection circuit 30 may be provided with multiple transistors coupled to one another in series to obtain a desired pinch-off voltage. FIG. 5 is a diagram illustrating a configuration example of the high-frequency integrated circuit 1 according to Modification Example 1 of the present disclosure. The protection circuit 30 of the high-frequency integrated circuit 1 includes the transistor M1, a transistor M2a, a transistor M2b, and a transistor M2c.

In the protection circuit 30, as illustrated in FIG. 5, the diode-coupled transistors M2a, M2b, and M2c similar to the transistor M2 in the above-described embodiment are coupled in series. It may be said that the transistors M2a, M2b, and M2c are coupled in three stages. A source of the transistor M2a is electrically coupled to the terminal 20, and a gate and a drain of the transistor M2a are electrically coupled to a source of the transistor M2b. A gate and a drain of the transistor M2b are electrically coupled to a source of the transistor M2c. Furthermore, a gate and a drain of the transistor M2c are electrically coupled to the grounding wire.

In this way, the source of the transistor M2a is coupled to the terminal 20 side, and the gate and the drain of the transistor M2a are coupled to the source side of the transistor M2b. The gate and the drain of the transistor M2b are coupled to the source side of the transistor M2c. It is to be noted that the transistor M2a is electrically coupled to the grounding wire through the transistors M2b and M2c. Furthermore, the transistor M2b is electrically coupled to the grounding wire through the transistor M2c.

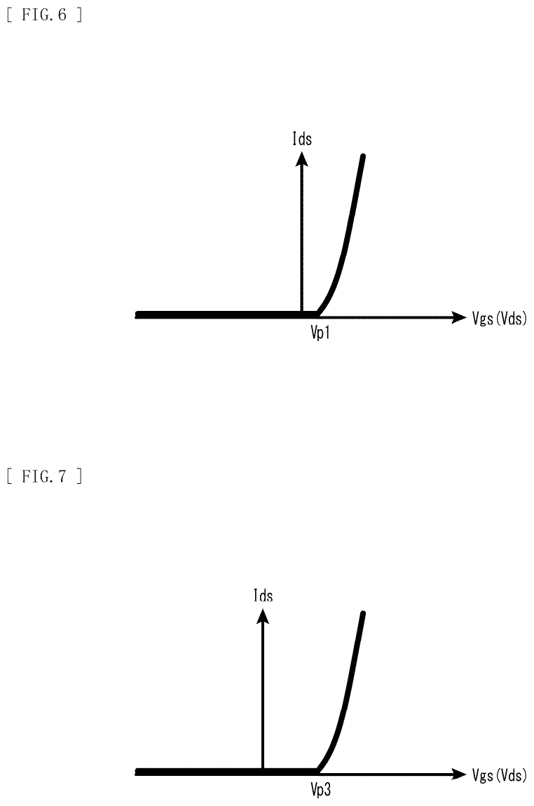

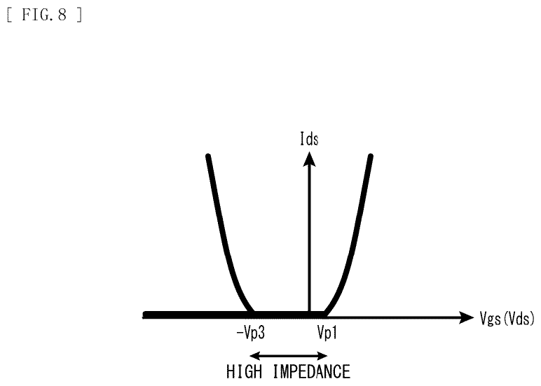

FIG. 6 is a diagram illustrating an example of electric characteristics of the transistor M1 for a positive surge. FIG. 7 is a diagram illustrating an example of electric characteristics of the transistors M2a to M2c for a negative surge. The transistor M1 for a positive surge has current-voltage characteristics illustrated in FIG. 6. Furthermore, as illustrated in FIG. 7, a pinch-off voltage Vp3 of the series-coupled transistors M2a to M2c is higher than a pinch-off voltage Vp1 of the transistor M1 for a positive surge illustrated in FIG. 6.

FIG. 8 is a diagram illustrating an example of electric characteristics of the parallel-coupled transistors M1 and M2a to M2c. When the value of the voltage Vgs, i.e., the voltage of the terminal 20 based on the grounding wire is within a range of −Vp3 to +Vp1, the transistors M1 and M2a to M2c all go into the off-state and the high-impedance state. When the voltage of the terminal 20 is greater than or equal to +Vp1, the transistor M1 goes into the on-state and the low-impedance state. Furthermore, when the voltage of the terminal 20 is less than or equal to −Vp3, the transistors M2a to M2c go into the on-state and the low-impedance state. In this way, in the present modification example, it is possible to extend the range of negative voltage that allows a high impedance.

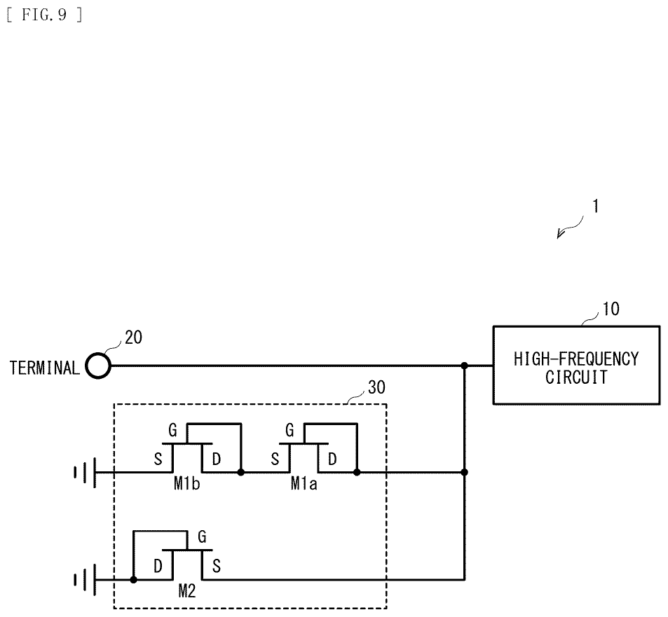

It is to be noted that the protection circuit 30 may be provided with multiple diode-coupled transistors similar to the transistor M1 in the above-described embodiment. For example, as illustrated in FIG. 9, transistors M1a and M1b coupled to each other in series may be provided. It may be said that the transistors M1a and M1b are coupled in two stages. A gate and a drain of the transistor M1a are coupled to the terminal 20 side, and a source of the transistor M1a is coupled to a gate and a drain of the transistor M1b. A source of the transistor M1b is coupled to the grounding wire side. It is to be noted that the transistor M1a is electrically coupled to the grounding wire through the transistor M1b. In an example illustrated in FIG. 9, by providing the transistors M1a and M1b, it becomes possible to extend the range of positive voltage that allows a high impedance.

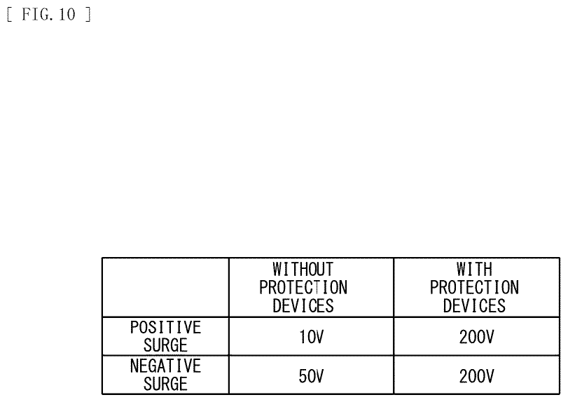

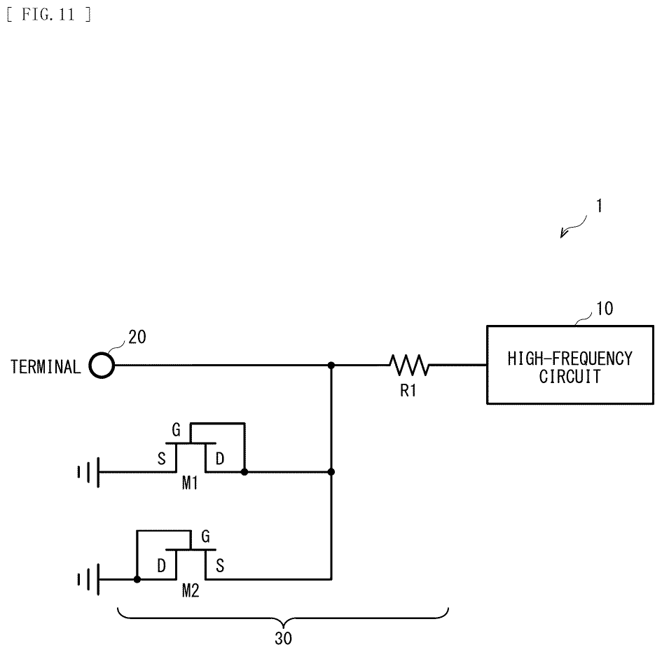

FIG. 10 is a diagram illustrating an example of an ESD evaluation result of the high-frequency integrated circuit 1 according to Modification Example 1 of the present disclosure. FIG. 10 presents a result of a human body model (HBM) test conducted on the high-frequency integrated circuit 1 illustrated in FIG. 5 using a charged human body model (on conditions of 100 pF and 1500Ω). FIG. 10 presents a withstand voltage against a positive surge and a withstand voltage against a negative surge in cases of with and without protection devices (the transistors M1 and M2a to M2c). It turns out that in the case of without protection devices, respective HBM withstand voltages against positive and negative surges are both less than or equal to 100 V; however, by providing the protection devices of the present disclosure, the HBM withstand voltages are greatly raised to 200 V or more.

### 2-2. Modification Example 2

FIG. 11 is a diagram illustrating a configuration example of the high-frequency integrated circuit 1 according to Modification Example 2 of the present disclosure. The protection circuit 30 of the high-frequency integrated circuit 1 includes a resistor R1 in addition to the transistors M1 and M2. The resistor R1 is a resistor, and is provided between the terminal 20 and the high-frequency circuit 10. Furthermore, the resistor R1 is located between the high-frequency circuit 10 and the transistors of the protection circuit 30. The high-frequency circuit 10 is electrically coupled to each of the transistors M1 and M2 of the protection circuit 30 through the resistor R1. It is to be noted that the resistance value of the resistor R1 only has to be appropriately adjusted in accordance with the type of ESD and the operating frequency of the high-frequency circuit 10, and may be set to be greater than or equal to 1 kΩ. The resistance value of the resistor R1 may be appropriately selected to allow a time constant to have a desired value. The resistance value of the resistor R1 may be set to, for example, a value greater than or equal to 1 kΩ and less than or equal to 100 KΩ.

There is a possibility that depending on the ESD time constant, the high-frequency circuit 10 may be broken before the protection circuit 30 discharges a surge. Thus, in the present modification example, the resistor R1 is formed between the high-frequency circuit 10 and the terminal 20, which makes it possible to delay the transmission of a surge to the high-frequency circuit 10. Before a voltage input to the high-frequency circuit 10 reaches the withstand voltage of the high-frequency circuit 10, an electric charge is able to be discharged by the protection circuit 30; thus, it is possible to protect the high-frequency circuit 10.

### 2-3. Modification Example 3

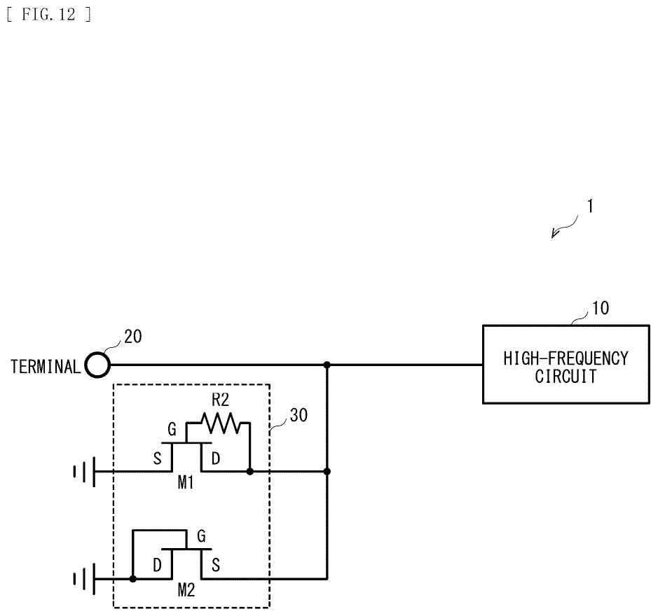

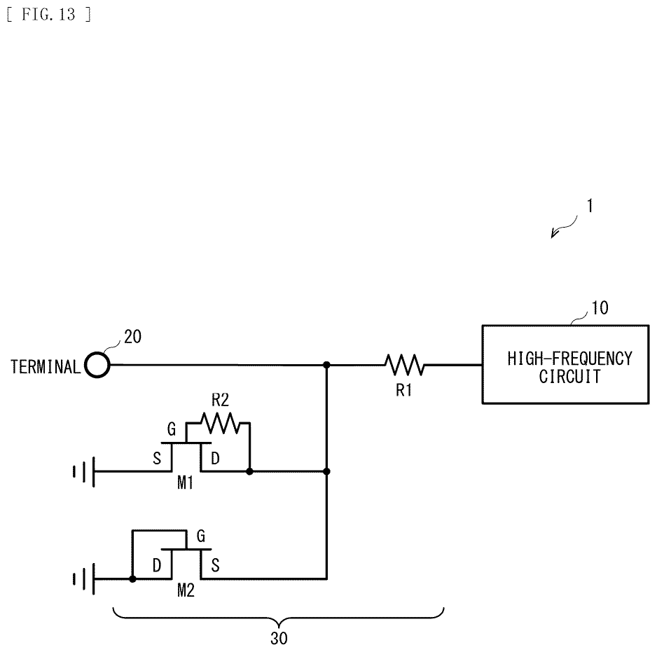

FIG. 12 is a diagram illustrating a configuration example of the high-frequency integrated circuit 1 according to Modification Example 3 of the present disclosure. The protection circuit 30 according to the present modification example includes a resistor R2 as illustrated in FIG. 12. The resistor R2 is a resistor, and is provided between the gate and the drain of the transistor M1. The gate of the transistor M1 is electrically coupled to the drain of the transistor M1 through the resistor R2. It is to be noted that the resistance value of the resistor R2 only has to be appropriately adjusted in accordance with the type of ESD and the operating frequency of the high-frequency circuit 10, and may be set to be greater than or equal to 1 kΩ. The resistance value of the resistor R2 may be appropriately selected to allow a time constant to have a desired value. The resistance value of the resistor R2 may be set to, for example, a value greater than or equal to 1 kΩ and less than or equal to 100 kΩ.

There is a possibility that depending on the ESD time constant, the gate of the transistor M1 may be broken before a current flows between the drain and the source of the transistor M1. Thus, in the present modification example, the resistor R2 is formed between the gate and the drain of the transistor M1, which delays the transmission of a surge to the gate of the transistor M1 and causes the current to start flowing between the drain and the source first: thus, it is possible to prevent the gate of the transistor M1 from being broken. It is to be noted that, the protection circuit 30 may include the above-described resistor R1 and the resistor R2 as illustrated in FIG. 13.

### 2-4. Modification Example 4

In the above-described embodiment, the configuration example of the transistor used as a protection device has been described; however, the configuration of the transistor is not limited to this. The transistors M1 and M2 may have a MIS gate structure, or may have a Schottky gate structure. Furthermore, the transistors M1 and M2 may be a depletion-type transistor. Instead of the field-effect transistor, a bipolar transistor may be used. For example, in accordance with the voltage range of a high-frequency signal to be input or output to the terminal 20, one or both of the transistor M1 and the transistor M2 may be a depletion-type transistor or a bipolar transistor.

The high-frequency integrated circuit 1 may include a semiconductor other than GaN-based ones. For example, the high-frequency integrated circuit 1 may include a GaAs-based, InP-based, or SiGe-based compound semiconductor. The transistor used as a protection device may be formed with a GaAs-based, InP-based, or some other compound semiconductor material.

### 3. Application Example

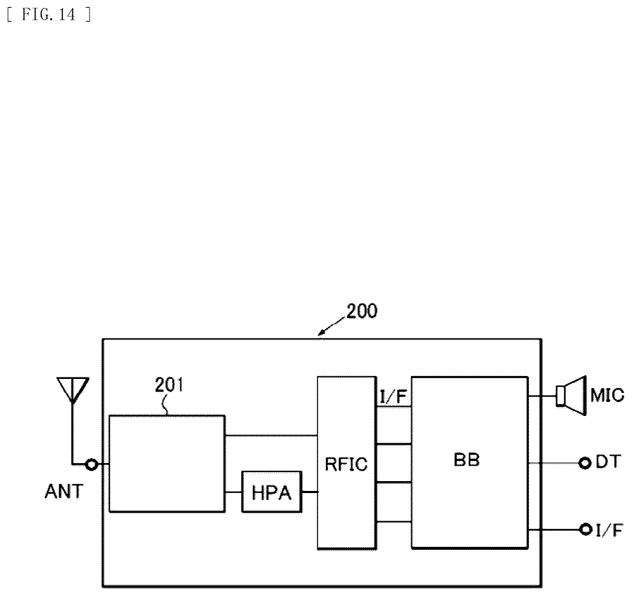

For example, the above-described high-frequency integrated circuit 1 is applicable to various electronic devices having a communication function. FIG. 14 is a diagram illustrating a configuration example of a wireless communication apparatus 200 of the present disclosure. As illustrated in FIG. 14, the wireless communication apparatus 200 includes an antenna ANT, an antenna switch circuit 201, a high-power amplifier HPA, a high-frequency integrated circuit RFIC, a baseband unit BB, an audio output unit MIC, a data output unit DT, and an interface unit I/F. The interface unit I/F is, for example, an interface circuit using a wireless local area network (W-LAN), a Bluetooth (registered trademark), or something else. The wireless communication apparatus 200 is, for example, a cell-phone system having multiple functions such as voice and data communications, LAN connection, etc.

The high-frequency integrated circuit including any of the protection circuits according to the above-described embodiment or modification examples is applied to the antenna switch circuit 201, the high-power amplifier HPA, the high-frequency integrated circuit RFIC, the baseband unit BB, or something of the wireless communication apparatus 200. For example, by applying a technique according to the present disclosure to the antenna switch circuit 201, the baseband unit BB, etc., it becomes possible to effectively suppress ESD damage in the wireless communication apparatus 200.

As above, the present disclosure has been described with the embodiment, the modification examples, the application example, and a practical application example; however, the present technology is not limited to the above-described embodiment, etc., and it is possible to make various modifications. For example, the above-described modification examples have been described as a modification example of the above-described embodiment; it is possible to appropriately combine the respective configurations of the modification examples.

It is to be noted that the effects described in the present specification are merely an example and are not limited to that description, and the present disclosure may have other effects. Furthermore, the present disclosure is able to have the following configurations.

(1)

A high-frequency integrated circuit including:
a high-frequency circuit;
a terminal electrically coupled to the high-frequency circuit;
a first transistor provided between the terminal and a reference potential line; and
a second transistor provided between the terminal and the reference potential line, in which
the first transistor includes a gate and a drain that are electrically coupled to the terminal, and a source electrically coupled to the reference potential line, and
the second transistor includes a source electrically coupled to the terminal, and a gate and a drain that are electrically coupled to the reference potential line.
   (2)

The high-frequency integrated circuit according to (1), in which
one or both of the first transistor and the second transistor is an enhancement-type transistor.
   (3)

The high-frequency integrated circuit according to (1) or (2), including a third transistor provided between the second transistor and the reference potential line, in which
the gate and the drain of the second transistor are electrically coupled to the reference potential line through the third transistor, and
the third transistor includes a source electrically coupled to the gate and the drain of the second transistor, and a gate and a drain that are electrically coupled to the reference potential line.
   (4)

The high-frequency integrated circuit according to any one of (1) to (3), including a fourth transistor provided between the first transistor and the reference potential line, in which
the source of the first transistor is electrically coupled to the reference potential line through the fourth transistor, and
the fourth transistor includes a gate and a drain that are electrically coupled to the source of the first transistor, and a source electrically coupled to the reference potential line.
   (5)

The high-frequency integrated circuit according to any one of (1) to (4), including a first resistor provided between the terminal and the high-frequency circuit, in which
the high-frequency circuit is electrically coupled to the first transistor and the second transistor through the first resistor.
   (6)

The high-frequency integrated circuit according to (5), in which
a resistance value of the first resistor is greater than or equal to 1 kΩ.
   (7)

The high-frequency integrated circuit according to any one of (1) to (6), including a second resistor provided between the gate of the first transistor and the drain of the first transistor.

(8)

The high-frequency integrated circuit according to (7), in which
a resistance value of the second resistor is greater than or equal to 1 kΩ.
   (9)

The high-frequency integrated circuit according to any one of (1) to (8), in which
a current flows through the first transistor when a positive surge voltage is generated in the terminal, and
a current flows through the second transistor when a negative surge voltage is generated in the terminal.
   (10)

The high-frequency integrated circuit according to any one of (1) to (9), in which
a current is less than or equal to 1 μA when the first transistor or the second transistor has a high impedance.
   (11)

The high-frequency integrated circuit according to any one of (1) to (10), in which
the first transistor and the second transistor are metal-insulator-semiconductor transistors.
   (12)

The high-frequency integrated circuit according to (11), in which
a film thickness of a gate insulating film of the first transistor is different from a film thickness of a gate insulating film of the second transistor.
   (13)

The high-frequency integrated circuit according to any one of (1) to (12), including a substrate provided with the high-frequency circuit, in which
the first transistor and the second transistor are provided on the substrate.
   (14)

The high-frequency integrated circuit according to (13), in which
the substrate is a silicon substrate.
   (15)

An electronic device including:
a high-frequency circuit;
a terminal electrically coupled to the high-frequency circuit;
a first transistor provided between the terminal and a reference potential line; and
a second transistor provided between the terminal and the reference potential line, in which
the first transistor includes a gate and a drain that are electrically coupled to the terminal, and a source electrically coupled to the reference potential line, and
the second transistor includes a source electrically coupled to the terminal, and a gate and a drain that are electrically coupled to the reference potential line.

The present application claims the benefit of Japanese Priority Patent Application JP2021-192215 filed with the Japan Patent Office on Nov. 26, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A high-frequency integrated circuit comprising:
a high-frequency circuit;
a terminal electrically coupled to the high-frequency circuit;
a first transistor provided between the terminal and a reference potential line; and
a second transistor provided between the terminal and the reference potential line, wherein
the first transistor includes a gate and a drain that are electrically coupled to the terminal, and a source electrically coupled to the reference potential line, and
the second transistor includes a source electrically coupled to the terminal, and a gate and a drain that are electrically coupled to the reference potential line.

2. The high-frequency integrated circuit according to claim 1, wherein
one or both of the first transistor and the second transistor is an enhancement-type transistor.

3. The high-frequency integrated circuit according to claim 1, comprising a third transistor provided between the second transistor and the reference potential line, wherein
the gate and the drain of the second transistor are electrically coupled to the reference potential line through the third transistor, and
the third transistor includes a source electrically coupled to the gate and the drain of the second transistor, and a gate and a drain that are electrically coupled to the reference potential line.

4. The high-frequency integrated circuit according to claim 1, comprising a fourth transistor provided between the first transistor and the reference potential line, wherein
the source of the first transistor is electrically coupled to the reference potential line through the fourth transistor, and
the fourth transistor includes a gate and a drain that are electrically coupled to the source of the first transistor, and a source electrically coupled to the reference potential line.

5. The high-frequency integrated circuit according to claim 1, comprising a first resistor provided between the terminal and the high-frequency circuit, wherein
the high-frequency circuit is electrically coupled to the first transistor and the second transistor through the first resistor.

6. The high-frequency integrated circuit according to claim 5, wherein
a resistance value of the first resistor is greater than or equal to 1 kΩ.

7. The high-frequency integrated circuit according to claim 1, comprising a second resistor provided between the gate of the first transistor and the drain of the first transistor.

8. The high-frequency integrated circuit according to claim 7, wherein
a resistance value of the second resistor is greater than or equal to 1 kΩ.

9. The high-frequency integrated circuit according to claim 1, wherein
a current flows through the first transistor when a positive surge voltage is generated in the terminal, and
a current flows through the second transistor when a negative surge voltage is generated in the terminal.

10. The high-frequency integrated circuit according to claim 1, wherein
a current is less than or equal to 1 μA when the first transistor or the second transistor has a high impedance.

11. The high-frequency integrated circuit according to claim 1, wherein
the first transistor and the second transistor are metal-insulator-semiconductor transistors.

12. The high-frequency integrated circuit according to claim 11, wherein
a film thickness of a gate insulating film of the first transistor is different from a film thickness of a gate insulating film of the second transistor.

13. The high-frequency integrated circuit according to claim 1, comprising a substrate provided with the high-frequency circuit, wherein
the first transistor and the second transistor are provided on the substrate.

14. The high-frequency integrated circuit according to claim 13, wherein
the substrate is a silicon substrate.

15. An electronic device comprising:
a high-frequency circuit;
a terminal electrically coupled to the high-frequency circuit;
a first transistor provided between the terminal and a reference potential line; and
a second transistor provided between the terminal and the reference potential line, wherein
the first transistor includes a gate and a drain that are electrically coupled to the terminal, and a source electrically coupled to the reference potential line, and
the second transistor includes a source electrically coupled to the terminal, and a gate and a drain that are electrically coupled to the reference potential line.
